(19) United States
(12) Patent Application Publication
(10) Pub. No.: US 2022/0084901 A1
(43) Pub. Date: Mar. 17, 2022

(54) SEMICONDUCTOR APPARATUS AND SEMICONDUCTOR APPARATUS MANUFACTURING METHOD

(71) Applicant: FUJI ELECTRIC CO., LTD., Kawasaki-shi (JP)

(72) Inventor: Shinichiro ADACHI, Kawasaki-shi (JP)

(73) Assignee: FUJI ELECTRIC CO., LTD., Kawasaki-shi (JP)

(21) Appl. No.: 17/464,033

(22) Filed: Sep. 1, 2021

(30) Foreign Application Priority Data
Sep. 17, 2020 (JP) 2020-156431

(51) Int. Cl. H01L 23/367; H01L 21/48

(52) U.S. Cl. CPC H01L 23/3672; H01L 21/4882

(57) ABSTRACT

A semiconductor apparatus includes a cooler including a top plate, a bottom plate having upper and lower surfaces opposite to each other, a plurality of fins, each of which is bonded between the top plate and the upper surface of the bottom plate, and a circumferential wall surrounding the plurality of fins and being bonded between the top plate and the upper surface of the bottom plate. A flow path for cooling water is formed by a space defined by the top plate, the plurality of fins, the circumferential wall and the bottom plate. The apparatus further includes a semiconductor element on the insulating substrate with an insulating substrate interposed therebetween. The lower surface of the bottom plate is a flat surface, and the upper surface of the bottom plate is warped so that a center thereof protrudes with respect to a periphery thereof toward the semiconductor element.

### CROSS REFERENCE TO RELATED APPLICATIONS

This application is based upon and claims the benefit of priority of the prior Japanese Patent Application No. 2020-156431, filed on Sep. 17, 2020, the entire contents of which are incorporated herein by reference.

### BACKGROUND OF THE INVENTION

### Field of the Invention

The present invention relates to a semiconductor apparatus and a semiconductor apparatus manufacturing method.

### Description of the Related Art

A semiconductor apparatus has a substrate having thereon semiconductor elements such as an insulated gate bipolar transistor (IGBT), a power metal oxide semiconductor field effect transistor (MOSFET) and a free wheeling diode (FWD) and is utilized in, for example, an inverter apparatus.

In this type of semiconductor module, an apparatus in which a cooler is integrated has been proposed. Semiconductor elements are disposed on a predetermined circuit substrate (which may be called an insulating substrate) and is mounted on a cooler with a bonding material such as solder. The cooler includes a top plate on which semiconductor elements and so on are mounted, heat dissipation fins, a bottom plate, a flange portion that includes an inlet portion and an outlet portion for a coolant and so on. Heat generated by an operation of the semiconductor module is dissipated through a coolant that circulates inside the cooler, and the semiconductor elements are thus cooled (see Japanese Patent Laid-Open No. 2020-92250, Japanese Patent Laid-Open No. 2018-49861, and Japanese Patent Laid-Open No. 2013-65609).

By the way, when semiconductor elements are soldered to a top plate of a cooler as described above with an insulating substrate interposed therebetween, the cooler, the insulating substrate and the semiconductor elements are exposed to an atmosphere at a significantly high temperature. At that time, the cooler may have a warpage caused by heat distortion. For example, while the cooler is made of metal such as aluminum or copper, the insulating substrate is made of ceramic such as alumina. Because of the difference in the coefficient of linear expansion between these members, a resultant warpage occurs in a predetermined direction at their interface.

The flatness of a bottom surface of the cooler exposed to a high temperature varies depending on the soldering temperature, the material or materials and structure of the cooler, and the material or materials and structure of the insulating substrate. With a specific combination of those materials and so on, the flatness of the bottom surface may be lost to an extent that the bottom surface of the cooler and a housing cannot be sealed.

As a result, a gap may occur in a cooler-fastened part that is a sealing area with a housing of, for example, an inverter. Accordingly, an expensive liquid gasket or an oddly-shaped rubber seal member rather than an inexpensive O-ring is required to be used. Therefore, there is a risk in that the configuration for acquiring the sealing of the cooler becomes a cost-increasing factor.

An object of the present invention, which has been made in view of such a point, is to provide a semiconductor apparatus and a semiconductor apparatus manufacturing method by which sealing can be acquired with an inexpensive configuration.

### SUMMARY OF THE INVENTION

A semiconductor apparatus according to one aspect of the present invention includes a cooler having a top plate, one surface of which serves as a heat dissipation surface, a plurality of fins provided on the heat dissipation surface, a circumferential wall part provided so as to surround outer circumferences of the plurality of fins, and a bottom plate bonded to distal ends of the circumferential wall part and the plurality of fins, wherein a flow path for cooling water is formed from a space defined by the top plate, the plurality of fins, the circumferential wall part and the bottom plate, and a semiconductor element disposed on the other surface of the top plate with an insulating substrate interposed therebetween. The center of an upper surface of the bottom plate warps upward, and a lower surface of the bottom plate is machined so as to be flat.

A semiconductor apparatus manufacturing method according to one aspect of the present invention is a manufacturing method for a semiconductor apparatus having a cooler having a top plate, one surface of which serves as a heat dissipation surface, a plurality of fins provided on the heat dissipation surface, a circumferential wall part provided so as to surround outer circumferences of the plurality of fins, and a bottom plate bonded to distal ends of the circumferential wall part and the plurality of fins, wherein a flow path for cooling water is formed from a space defined by the top plate, the plurality of fins, the circumferential wall part and the bottom plate, the method including the steps of disposing a semiconductor element on the other surface of the top plate with an insulating substrate interposed therebetween, and performing flat machining on a lower surface of the bottom plate.

### Advantageous Effect of Invention

According to the present invention, sealing can be acquired with an inexpensive configuration.

### BRIEF DESCRIPTION OF THE DRAWINGS

FIG. 1 is a plan view of a semiconductor apparatus according to an embodiment;

FIG. 2 is a cross-sectional view of the semiconductor apparatus according to the embodiment;

FIG. 3 is a plan view of an internal part of a cooler according to the embodiment viewed from its lower surface side;

FIG. 4 is a plan view of a state that a bottom plate is attached to the lower surface side of the cooler shown in FIG. 3;

FIGS. 5A and 5B are cross-sectional views of a semiconductor apparatus according to a comparative example;

FIG. 6 is a schematic diagram showing one step example of a manufacturing method for the semiconductor apparatus according to the embodiment;

FIG. 7 is a schematic diagram showing one step example of the manufacturing method for the semiconductor apparatus according to the embodiment;

FIG. 8 is a schematic diagram showing one step example of the manufacturing method for the semiconductor apparatus according to the embodiment;

FIG. 9 is a schematic diagram showing one step example of the manufacturing method for the semiconductor apparatus according to the embodiment;

FIG. 10 is a schematic diagram showing one step example of the manufacturing method for the semiconductor apparatus according to the embodiment;

FIG. 11 is a schematic diagram showing one step example of the manufacturing method for the semiconductor apparatus according to the embodiment;

FIG. 12 is a bottom view of a cooler according to a modification example; and

FIGS. 13A and 13B are bottom views of a cooler according to modification examples.

### DETAILED DESCRIPTION OF THE PREFERRED EMBODIMENT

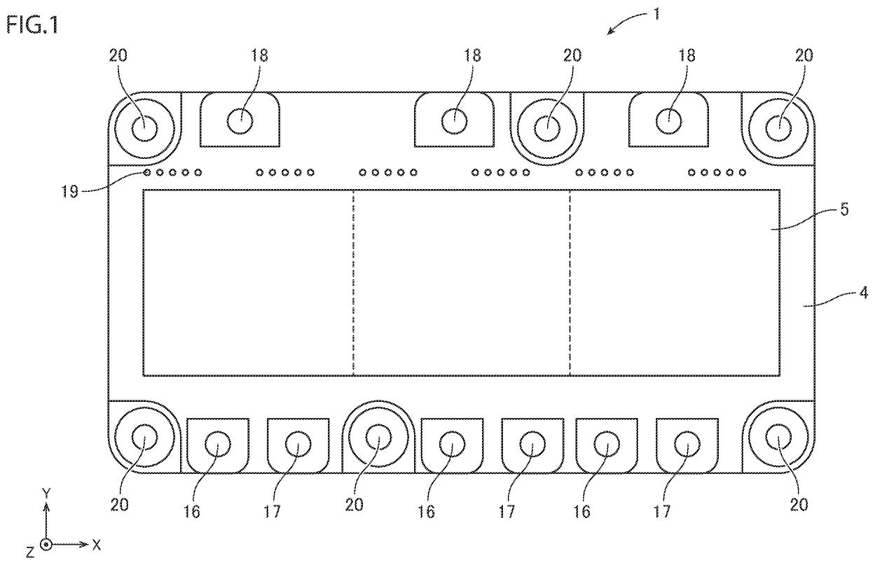

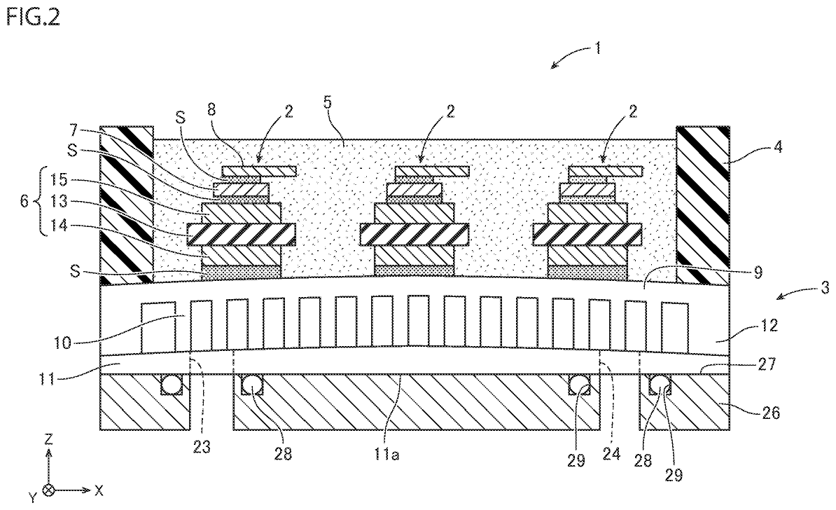

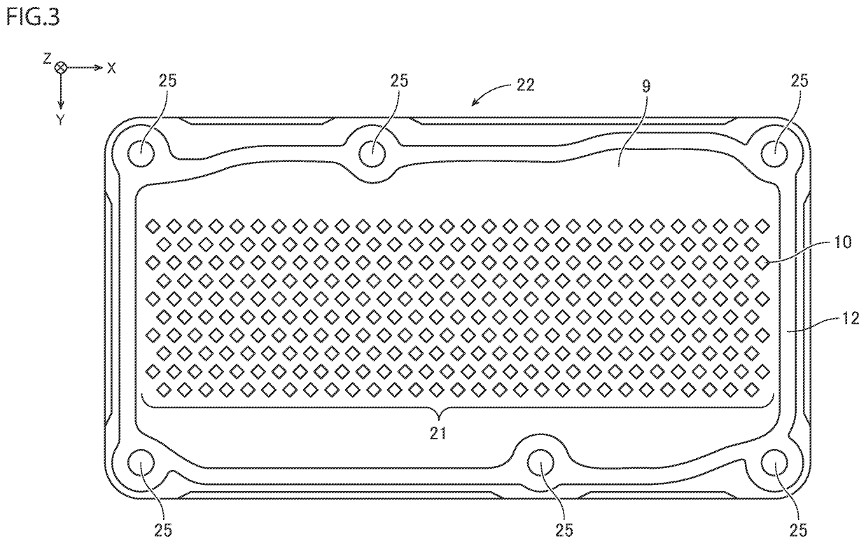

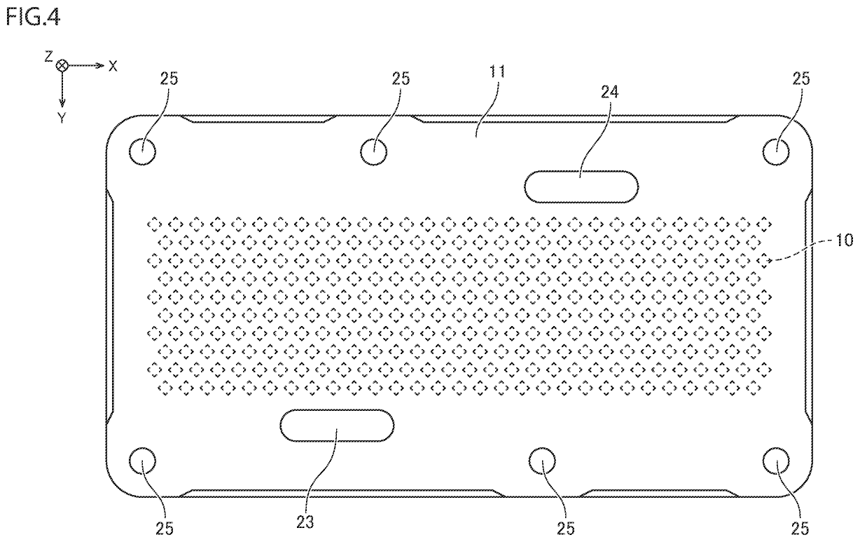

A semiconductor apparatus to which the present invention is applicable is described below. FIG. 1 is a plan view of a semiconductor apparatus according to an embodiment. FIG. 2 is a cross-sectional view of the semiconductor apparatus according to the embodiment. FIG. 3 is a plan view of an internal part of a cooler according to the embodiment viewed from its lower surface side. FIG. 4 is a plan view of a state that a bottom plate is attached to the lower surface side of the cooler shown in FIG. 3. The semiconductor apparatus to be described below is merely an example, and changes can be made as appropriate without limiting thereto.

In the following drawings, a longitudinal direction of the semiconductor apparatus (or a direction in which a plurality of semiconductor modules are aligned), a transverse direction of the semiconductor apparatus and a height direction (direction of thickness of a substrate) are defined as an X direction, a Y direction and a Z direction, respectively. The shown axes of X, Y, Z are orthogonal to each other and form a right-handed system. In some cases, the X direction, the Y direction and the Z direction may be called a right-left direction, a front-back direction and a top-bottom direction, respectively. These directions (front-back, right-left, and top-bottom directions) are words used for convenience of description, and the correspondence relationships with the X, Y, Z directions may change depending on the attached attitude of the semiconductor apparatus. For example, a heat dissipation surface side (cooler side) of the semiconductor apparatus is called a lower surface side, and the opposite side is called an upper surface side. The planar view herein refers to a view of the upper surface of the semiconductor apparatus from the Z-direction positive side.

A semiconductor apparatus 1 according to the embodiment is applied to a power converter such as a power control unit and is a power semiconductor module included in an inverter circuit. As shown in FIG. 1 and FIG. 2, the semiconductor apparatus 1 includes a plurality of (three in this embodiment) semiconductor assemblies 2, a cooler 3 that cools the semiconductor assemblies 2, a case member 4 that accommodates the plurality of semiconductor assemblies 2, and a sealing resin 5 injected into the case member 4.

The semiconductor assemblies 2 include a plurality of insulating substrates 6, a plurality of semiconductor elements 7 disposed on the insulating substrates 6, and a metallic wiring plate 8 disposed on each of the semiconductor elements 7. According to this embodiment, three semiconductor assemblies 2 are disposed side by side in the X direction. The three semiconductor assemblies 2 constitute a U phase, a V phase and a W phase from, for example, the X-direction positive side and form a three-phase inverter circuit as a whole. It should be noted that the semiconductor assemblies 2 may be called power cells or units.

The cooler 3 has a rectangular shape in planar view and includes a top plate 9, a plurality of fins 10 (see FIG. 3) provided on the top plate 9, and a bottom plate 11. The fins 10 are provided on an inner surface (heat dissipation surface) of the top plate 9 on the opposite side of an outer surface (boding surface) to which the insulating substrates 6 are bonded, details of which are described later. The top plate 9 has a circumferential wall part 12 that surrounds outer circumferences of the plurality of fins 10. The bottom plate 11, which is described later, is bonded to distal ends of the plurality of fins 10 and the circumferential wall part 12. In addition to the plurality of fins 10, an auxiliary fin and a guide each having a distal end that is not bonded to the bottom plate 11 may be provided on the top plate 9.

The insulating substrates 6 are disposed on the upper surface of the top plate 9 with a bonding material S such as solder. The insulating substrates 6 are composed of, for example, a direct copper bonding (DCB) substrate, an active metal brazing (AMB) substrate or a metallic base substrate. More specifically, the insulating substrates 6 have an insulating plate 13, a heat dissipation plate 14 disposed on a lower surface of the insulating plate 13, and a circuit plate 15 disposed on an upper surface of the insulating plate 13. The insulating substrates 6 have, for example, a rectangular shape in planer view.

The insulating plate 13 is formed by, for example, an insulating material such as a ceramics material such as alumina (Al₂O₃), aluminum nitride (AlN) or silicon nitride (Si₃N₄), a resin material such as epoxy, or an epoxy resin material having a ceramics material as a filler. It should be noted that the insulating plate 13 may be called an insulating layer or an insulating film.

The heat dissipation plate 14 has a predetermined thickness in the Z direction and is formed so as to cover the entire lower surface of the insulating plate 13. The heat dissipation plate 14 is formed by a metallic plate having good heat conductivity of, for example, copper or aluminum.

The circuit plate 15 is provided on the upper surface of the insulating plate 13. Although FIG. 2 shows only one circuit plate 15 for convenience of description, more circuit plates 15 may be formed on the upper surface of the insulating plate 13. These circuit plates 15 are metallic layers of, for example, a copper foil and are formed in land shapes on the insulating plate 13 such that the circuit plates 15 are electrically insulated from each other.

The semiconductor element 7 is disposed on the upper surface of the circuit plate 15 with the bonding material S such as solder. The semiconductor element 7 is, for example, square-shaped in planer view.

The semiconductor element 7 is disposed on the upper surface of the circuit plate 15 with the bonding material S and is electrically connected thereto. Although FIG. 2 shows one semiconductor element 7 for one circuit plate 15 for convenience, more semiconductor elements 7 may be disposed on the circuit plate 15. The semiconductor element 7 is square shaped (rectangular shaped) in planar view and is formed from a semiconductor substrate of, for example, silicon (Si), silicon carbide (SiC), gallium nitride (GaN) and diamond.

As the semiconductor element 7, an insulated gate bipolar transistor (IGBT), a switching element such as a power metal oxide semiconductor field effect transistor (MOSFET), or a diode such as a free wheeling diode (FWD) is used. Alternatively, as the semiconductor element 7, a reverse conducting (RC)—IGBT element in which an IGBT and an FWD are integrated, a power MOSFET element, a reverse blocking (RB)—IGBT having a sufficient resistance to pressure against a reverse bias or the like may be used.

The shape, number of positions or positions of the semiconductor elements 7 can be changed as required. Although the semiconductor element 7 according to this embodiment is a vertical switching element having a function element such as a transistor on the semiconductor substrate, the semiconductor element 7 is not limited thereto and may be a horizontal switching element.

The metallic wiring plate 8 may be disposed on an upper surface electrode of the semiconductor element 7 with the bonding material S such as solder. The metallic wiring plate 8 forms main wiring through which main current flows. The metallic wiring plate 8 is formed by, for example, press processing by using a metallic material such as a copper material, a copper-alloy-based material, an aluminum-alloy-based material or an iron-alloy-based material. The metallic wiring plate 8 has one end bonded to the upper surface electrode of the semiconductor element 7. The metallic wiring plate 8 has the other end, not particularly shown, bonded to an external terminal provided in the case member, which is described later. The shape of the metallic wiring plate 8 shown in FIG. 2 is merely an example and can be changed as required. The metallic wiring plate 8 may be, for example, a lead frame, a clip or a ribbon. Instead of the bonding material S and the metallic wiring plate 8, a wire or a ribbon may be connected as main wiring to the upper surface electrode of the semiconductor element 7.

The case member 4 is bonded to the upper surface of the top plate 9 with, for example, an adhesive (not shown). The case member 4 has a shape following an external shape of the top plate 9 of the cooler 3. The case member 4 has a rectangular frame shape that is open at its center. The aforementioned three semiconductor assemblies 2 are accommodated in the central opening. In other words, the three semiconductor assemblies 2 are surrounded by the frame-shaped case member 4.

The sealing resin 5 is filled in an inner space of the case member 4, details of which are described later. In other words, the case member 4 defines a space that accommodates the plurality of semiconductor assemblies 2 (the insulating substrates 6, the semiconductor elements 7 and the metallic wiring plates 8) and the sealing resin 5. This case member 4 is formed of a thermoplastic resin. The case member 4 is formed of, for example, a polyphenylene sulfide resin (PPS resin), a polybutylene terephthalate resin (PBT resin) or the like.

Main terminals (a P terminal 16, an N terminal 17, and an M terminal 18) for external connection and a control terminal 19 for control are provided in the case member 4. More specifically, the P terminal 16 and the N terminal 17 are embedded by molding in a wall part on the Y-direction negative side of a pair of wall parts that face each other in the transverse direction (Y direction) of the case member 4. One P terminal 16 and one N terminal 17 are provided for one semiconductor assemblies 2.

The M terminal 18 and the control terminal 19 are embedded by molding in a wall part on the Y-direction positive side of the pair of wall parts that face each other in the transverse direction (Y direction) of the case member 4. One M terminal 18 is provided for one semiconductor assembly 2. For example, 10 control terminals 19 are provided for one semiconductor assembly 2.

These terminals are formed of a metallic material such as a copper material, a copper-alloy-based material, an aluminum-alloy-based material or an iron-alloy-based material. The shapes, positions and numbers of those terminals are not limited to those described above but can be changed as required.

The case member 4 has a plurality of through-holes 20 along an outer edge of the case member 4. The through-holes 20 are holes for inserting screws (not shown) therethrough for fixing the semiconductor apparatus 1.

As described above, the sealing resin 5 is filled in an internal space provided by the frame-shaped case member 4. Thus, the insulating substrates 6, and the semiconductor elements 7 and the metallic wiring plates 8 mounted thereon are sealed within the space. The sealing resin 5 is formed of a thermosetting resin. The sealing resin 5 preferably contains at least one of epoxy, silicone, urethane, polyimide, polyamide, and polyamide-imide. As the sealing resin 5, for example, an epoxy resin to which a filler is mixed is preferable from viewpoint of its insulation property, heat resistance property and heat dissipation property.

Next, a detailed configuration of the cooler 3 is described. As shown in FIG. 2 to FIG. 4, the cooler 3 has a box shape formed by bonding the bottom plate 11 to the top plate 9 and integrating them. The cooler 3 is formed of, for example, an aluminum alloy having a good heat dissipation property. More specifically, the cooler 3 is preferably formed of a metallic material such as A6063, A3003, or A1050. A plating layer having a predetermined thickness is provided on a surface of the cooler 3. The plating layer is preferably formed of metallic plating of, for example, nickel.

The top plate 9 is rectangular-shaped in planer view and is formed by a plate-shaped body having a predetermined thickness. The top plate 9 has an external shape corresponding to the external shape of the case member 4. In other words, the top plate 9 has a longitudinal direction extending in the right-left direction (X direction) of the semiconductor apparatus 1 and a transverse direction extending in the front-back direction (Y direction) of the semiconductor apparatus 1. The top plate 9 has one surface (lower surface) and the other surface (upper surface). The one surface forms a heat dissipation surface of the semiconductor assemblies 2. The other surface forms a bonding surface of the semiconductor assemblies 2.

According to this embodiment, three semiconductor assemblies 2 are disposed in a central area of the upper surface of the top plate 9. As described above, the three semiconductor assemblies 2 are aligned in the X direction. It should be noted that, according to this embodiment, the central area of the lower surface side (heat dissipation surface side) of the top plate 9 on which the three semiconductor assemblies 2 described above are disposed is sometimes called a heat dissipation area.

The plurality of fins 10 are provided in the heat dissipation area of the lower surface of the top plate 9. The plurality of fins 10 may be formed of the same metallic material as the top plate 9 and may be provided integrally with the top plate 9. In other words, the fins 10 are used as a heat sink. For example, as the fins 10, pin fins can be used in which a plurality of prism-shaped pins (square pins) are arranged at predetermined pitches with an interval therebetween, as shown in FIG. 3. The fin shape may be a round pin, a corrugated fin or a straight fin.

More specifically, each of the fins 10 has a rhombus shape in planer view, and the facing direction where a pair of corners face each other on a diagonal line agrees with the transverse direction of the top plate 9. The fins 10 project by a predetermined length toward the Z-direction negative side. The configuration of the fins 10 provided on the top plate 9 is not limited thereto but can be changed as required. For example, cylindrical-shaped pins may be provided instead of the prism-shaped pins shown in FIG. 3, or a plurality of fins 10 having a blade shape extending in the front-back direction may be aligned in parallel with each other. The fins 10 may be provided to the top plate 9 by brazing, implanting, cutting processing or plastic working.

According to this embodiment, a collection 21 of the plurality of fins 10 is provided. The collection 21 of the fins 10 has an external shape having a substantially rectangular parallelepiped shape. More preferably, although the external shape of the collection 21 of the fins 10 is a rectangular parallelepiped shape, it is not limited thereto and may be rounded or deformed. The longitudinal direction of the collection 21 of the fins 10 agrees with the longitudinal direction of the top plate 9.

The lower surface of the top plate 9 has the circumferential wall part 12 that surrounds an outer circumference of the plurality of fins 10 (collection 21). The circumferential wall part 12 projects by a predetermined height from the lower surface of the top plate 9 toward the Z-direction negative side. The circumferential wall part 12 has a rectangular frame shape along the outer edge of the top plate 9. The projection height of the circumferential wall part 12 is preferably equal to the projection height of the fins 10.

The top plate 9 and the circumferential wall part 12 may be integrated with each other. In other words, the top plate 9 and the circumferential wall part 12 form a box-shaped cooling case 22 that is open downward. The bottom plate 11, which is described below, forms a lid part that closes the opening of the cooling case 22.

The bottom plate 11 is disposed on a lower surface of the cooling case 22 described above. The bottom plate 11 has the same rectangular shape in planer view as the top plate 9 and is formed as a plate-shaped body having a predetermined thickness. The bottom plate 11 is preferably formed of an aluminum alloy that is the same material as the cooling case 22. Also, the bottom plate 11 is preferably thicker than the top plate 9, details of which are described later.

The bottom plate 11 is bonded to distal ends of the circumferential wall part 12 and the plurality of fins 10 described above by brazing. Thus, the lower opening of the cooling case 22 is closed. In this way, a flow path for cooling water is formed by the space enclosed by the top plate 9, the plurality of fins 10, the circumferential wall part 12, and the bottom plate 11.

As shown in FIG. 4, an inlet portion 23 and a discharge portion 24 for the cooling water to and from the cooler 3 are provided at predetermined positions of the bottom plate 11. Each of the inlet portion 23 and the discharge portion 24 has a through-hole extending through the bottom plate 11 in the thickness direction. More specifically, the inlet portion 23 and the discharge portion 24 are disposed so as to face each other diagonally with the plurality of fins 10 interposed therebetween in the Y direction. Each of the inlet portion 23 and the discharge portion 24 has a long-hole shape that is long in the X direction in planar view. For example, the shape of the inlet portion 23 and the discharge portion 24 is an elliptical or oval shape that is short on the transverse direction side of the cooler 3 and is long on the longitudinal direction side. The shapes and positions of the inlet portion 23 and discharge portion 24 are not limited thereto but can be changed as required, details of which are described later.

The cooler 3 has a plurality of fixing holes 25 along the outer circumferential edge. The fixing holes 25 are provided correspondingly to the through holes 20 of the case member 4 described above.

The semiconductor apparatus 1 having the configuration as described above is attached to a flat installation surface 27 of a housing 26 of, for example, a power control unit, which is an installation destination with a gasket such as an O-ring 28 interposed therebetween. The power control unit may be a motor driving part including a power converter and a cooling device. In this case, the lower surface of the bottom plate 11 is in contact with the installation surface 27. Referring to FIG. 2, for example, the housing 26 has a groove 29 for the O-ring. Because of the O-ring 28, sealing between the installation surface 27 and the lower surface of the bottom plate 11 is acquired.

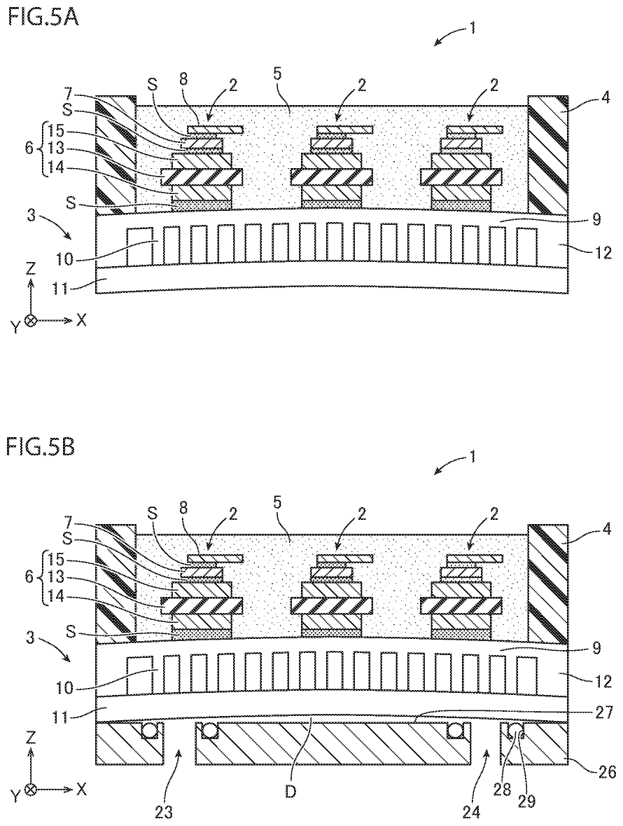

A general manufacturing method for the semiconductor apparatus 1 including the cooler 3 is now described with reference to FIG. 5. FIGS. 5A and 5B are cross-sectional views of a semiconductor apparatus according to a comparative example. The comparative example shown in FIG. 5 is only partially different from the semiconductor apparatus shown in FIGS. 1 to 4, and the basic configurations are common. Therefore, the common parts are referred to by the same numbers, and description is omitted as appropriate.

As described above, in the semiconductor apparatus 1 in which the cooler 3 and the plurality of semiconductor assemblies 2 are integrated, the plurality of semiconductor assemblies 2 are disposed on the upper surface of the cooler 3 with the bonding material S such as solder. Then, these components are inserted to, for example, a furnace and the solder is melted, so that the cooler 3 and the plurality of semiconductor assemblies 2 are bonded (see FIG. 5A).

As shown in FIG. 5A, in a series of processes until the solder is melted and cured, a warpage that projects upward at its center part occurs in the cooler 3 (particularly, the top plate 9 and the bottom plate 11). This is a phenomenon caused because the coefficients of linear expansion of the cooler 3 and the insulating substrate 6 are different.

For example, the cooler 3 is formed of an aluminum alloy and has a coefficient of linear expansion of 22 to 24 ppm. On the other hand, the insulating substrate 6 is formed of a ceramics material and has a coefficient of linear expansion of 2.8 to 7.2 ppm. In this way, the coefficient of linear expansion of the cooler 3 is higher than that of the insulating substrate 6. Thus, at the interface between the cooler 3 and the insulating substrate 6 (in the vicinity of the bonding material S), the cooler 3 thermally expands when the cooler 3 is exposed to a high temperature and contracts when the temperature decreases. On the other hand, the insulating substrate 6 does not thermally expand and thermally contract as much as the cooler 3 does. Therefore, the cooler 3 is pulled by the insulating substrate 6 at the interface when the cooler 3 thermally contracts. As a result, the whole cooler 3 warps.

When attachment of the semiconductor apparatus 1 with the warped cooler 3 (particularly bottom plate 11) to the installation surface 27 as the installation destination is attempted, a predetermined gap D as much as the warpage occurs between the installation surface 27 and the lower surface of the bottom plate 11 (see FIG. 5B).

In this case, in order to acquire sealing between the installation surface 27 and the bottom plate 11, the general O-ring 28 is insufficient, and, for example, a liquid gasket or a specially-shaped sealant is required to use. However, such a liquid gasket and specially-shaped sealant become a cost-increasing factor of the semiconductor apparatus 1 as a whole because the liquid gasket and specially-shaped sealant are expensive.

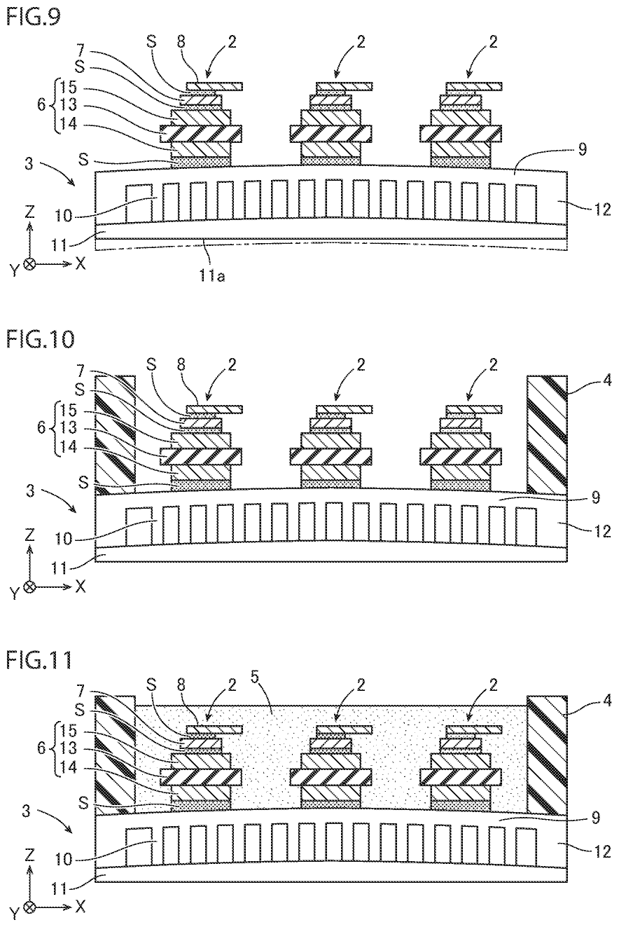

Accordingly, the present inventor has reached the present invention with focus on the warpage due to a difference in material between the cooler 3 and the insulating substrate 6. Specifically, according to this embodiment, as shown in FIG. 2 (FIG. 9), as a result of soldering the semiconductor assemblies 2 to the cooler 3, the whole cooler 3 warps while projecting upward toward the semiconductor elements 7. More specifically, the centers of the upper surfaces of the top plate 9 and the bottom plate 11 warp upward. Contrary to this, the lower surface of the bottom plate 11 is machined to be flat. As the result, a thickness of the bottom plate 11 at the center is greater than at a periphery.

With this configuration, because of the flat lower surface of the bottom plate 11, the gap D does not occur between the installation surface 27 and the bottom plate 11 when the semiconductor apparatus 1 is mounted on the installation destination. Thus, sufficient sealing can be acquired between the cooler 3 and the installation destination with the existing O-ring 28 interposed therebetween. This eliminates necessity for use of a liquid gasket or a specially-shaped sealant. Also, because machining the lower surface of the bottom plate 11 so as to be flat is only required, the sealing can be acquired with the inexpensive configuration.

Also, in this embodiment, the cooling case 22 in which the top plate 9, the circumferential wall part 12 and the plurality of fins 10 are integrated is provided. In this configuration, the components of the cooler 3 are formed from two parts of the cooling case 22 and the bottom plate 11. Therefore, the configuration of the cooler 3 can be simplified, and the number of man-hours for manufacturing and the cost for manufacturing can be reduced.

Also, in this embodiment, the lower surface of the bottom plate 11 has the inlet portion 23 and the discharge portion 24 for cooling water. In this configuration, the inlet portion 23 and the discharge portion 24 do not project from the sides of the bottom plate 11. Thus, without using a special joint or the like and only by attaching the semiconductor apparatus 1 to the installation destination, a cooling water path of the installation destination can be connected to the cooler 3. Therefore, the configuration can be simplified, and the number of man-hours for the attachment can be reduced.

Also, in this embodiment, the plurality of semiconductor elements 7 are disposed side by side in a predetermined direction (X direction). The cooler 3 has a rectangular shape in planar view that is long in the direction of alignment (X direction) of the semiconductor elements 7. Also, the inlet portion 23 and the discharge portion 24 are disposed with the plurality of fins 10 (a collection 21 of the fins 10) interposed therebetween. More specifically, the inlet portion 23 and the discharge portion 24 are disposed so as to diagonally face each other with the plurality of fins 10 interposed therebetween. The inlet portion 23 and the discharge portion 24 diagonally face each other, so that a long distance is provided between the inlet portion 23 and the discharge portion 24. Thus, they are easily influenced by displacements in the Z direction due to a warpage. In other words, a thickness of a part around the inlet portion 23 and the discharge portion 24 of the bottom plate 11 is smaller than a thickness of the other parts of the bottom plate 11. Therefore, the effect acquired by machining the lower surface of the bottom plate 11 so as to be flat is more significantly exerted.

Also, in this embodiment, the inlet portion 23 and the discharge portion 24 face each other in the transverse direction (Y direction) of the cooler 3, and the inlet portion 23 and/or the discharge portion 24 have a long-hole shape that is long in the direction of alignment (longitudinal direction). With this configuration, without increasing the width in the transverse direction of the cooler 3, the flow passage areas of the inlet portion 23 and/or the discharge portion 24 can be acquired.

Also, in this embodiment, the bottom plate 11 is thicker than the top plate 9. Specifically, the top plate 9 preferably has a thickness of 0.8 to 1.2 mm, and the bottom plate 11 preferably has a thickness of 2 to 5 mm. Because the bottom plate 11 functions as a surface to be sealed with the installation destination, the sealing can be sufficiently acquired by suppressing a deformation caused when the bottom plate 11 is fastened.

Also, in this embodiment, the bottom plate 11 is acquired by coating a surface of a metallic material with plating having a predetermined thickness, and a lower surface 11a of the metallic material is exposed on the machined lower surface of the bottom plate 11. Particularly, the lower surface of the bottom plate preferably has a flatness equal to or smaller than 100 μm. Thus, when the semiconductor apparatus 1 is attached to the installation destination, the sealing between the installation surface 27 and the lower surface of the bottom plate 11 can be effectively acquired. Also, whether the lower surface of the bottom plate has been machined or not can be determined.

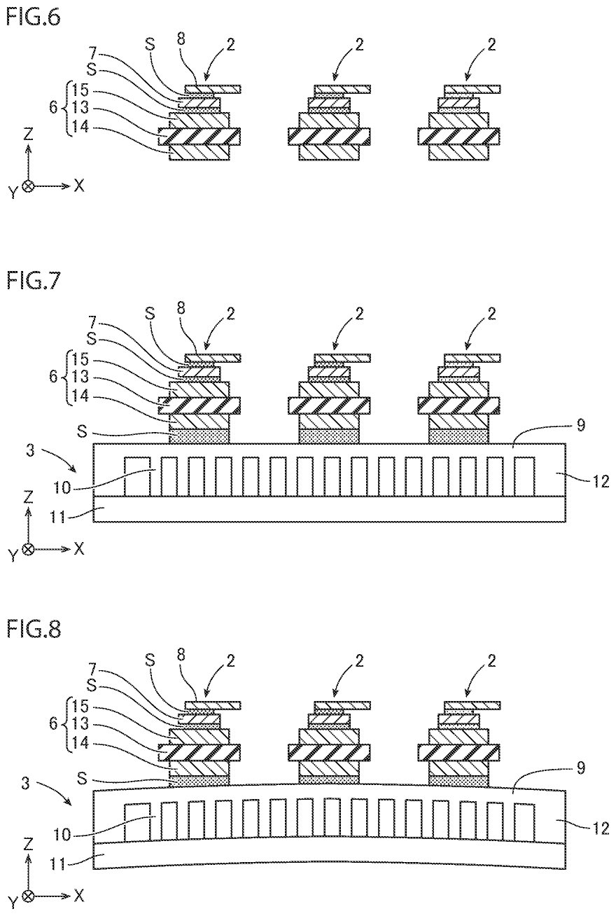

Next, with reference to FIG. 6 to FIG. 11, a manufacturing method for the semiconductor apparatus according to this embodiment is described. FIG. 6 to FIG. 11 are schematic diagrams showing step examples of the manufacturing method for the semiconductor apparatus according to this embodiment. The semiconductor apparatus manufacturing method, which is described below, is merely an example and can be changed as appropriate without limiting to the configuration.

The manufacturing method for the semiconductor apparatus 1 according to this embodiment includes the steps of assembling the semiconductor assembly 2 (unit) (unit assembling step), disposing the semiconductor assembly 2 on the cooler 3 (unit disposing step), bonding the semiconductor assembly 2 and the cooler 3 (unit bonding step), machining the lower surface of the cooler 3 (machining step), disposing the case member 4 (case disposing step), and sealing with the sealing resin 5 (sealing step). It should be noted that the order of these steps can be changed as appropriate as long as no contradiction arises. For example, the machining step may be performed after the case disposing step or the sealing step.

First, the unit assembling step is performed. As shown in FIG. 6, in the unit assembling step, the semiconductor element 7 is disposed on the upper surface of the insulating substrate 6 (circuit plate 15) with the bonding material S, and the metallic wiring plate 8 is disposed on the upper surface of the semiconductor element 7 with the bonding material S. These components are inserted to a furnace at a predetermined temperature and are bonded to each other.

Next, the unit disposing step is performed. As shown in FIG. 7, in the unit disposing step, the semiconductor assembly 2 is disposed on the upper surface of the cooler 3 (top plate 9) with the bonding material S. As shown in FIG. 7, three semiconductor assemblies 2 are disposed side by side in the X direction.

Next, the unit bonding step is performed. As shown in FIG. 8, the cooler 3 and the plurality of semiconductor assemblies 2 are inserted to a furnace at a predetermined temperature (such as 300° C.). Thus, the bonding material S is melted. The bonding material S is hardened by being further cooled, so that the cooler 3 and the plurality of semiconductor assemblies 2 are bonded. In this case, due to a difference in coefficient of linear expansion between the cooler 3 and the insulating substrate 6, a warpage that projects upward at its center part occurs in the cooler 3 (particularly, the top plate 9 and the bottom plate 11).

Next, the machining step is performed. As shown in FIG. 9, in the machining step, the lower surface of the bottom plate 11 of the cooler 3 is trimmed by machining to be flattened. It should be noted that the dash line part shown in FIG. 9 is the bottom surface part of the cooler 3 that originally exists before the flattening is performed. Specifically, the flattening is machining that trims the lower surface of the bottom plate 11 of the cooler 3 by 0.01 μm to 1 mm. In this case, the flatness of the lower surface of the bottom plate 11 after the flattening is preferably equal to or smaller than about 100 μm. It should be noted that a method for the machining may be performed by using various tools and machine tools. Also, because the surface of the cooler 3 is coated with plating having a predetermined thickness, it means that the surface 11a made of a metallic material is exposed on the machined lower surface of the bottom plate 11.

Next, the case disposing step is performed. As shown in FIG. 10, in the case disposing step, the case member 4 is disposed so as to surround the semiconductor assemblies 2 on the upper surface of the top plate 9. The case member 4 is bonded to the upper surface of the top plate 9 with, for example, an adhesive.

Next, the sealing step is performed. As shown in FIG. 11, in the sealing step, the liquid sealing resin 5 is filled in a space provided within the case member 4. The sealing resin 5 seals the semiconductor assemblies 2 disposed inside the case member 4. The sealing resin 5 is filled until its upper surface reaches the vicinity of the upper surface of the case member 4. When the sealing resin 5 is cured, the case member 4 and the semiconductor assemblies 2 are fixed. In this way, the semiconductor apparatus 1 is completed.

As described above, according to this embodiment, after the semiconductor element 7 is soldered to the upper surface of the cooler 3 with the insulating substrate 6 interposed therebetween, the lower surface of the cooler 3 is flattened by machining, so that sealing between the cooler 3 and the installation destination can be acquired with an inexpensive configuration.

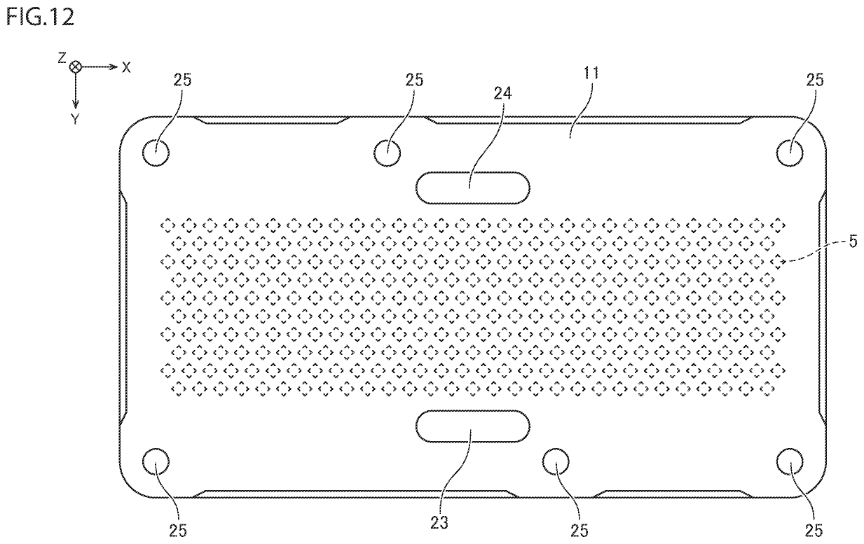

It should be noted that, having described the case of, according to the aforementioned embodiment, disposing the inlet portion 23 and the discharge portion 24 so as to diagonally face each other, the present invention is not limited to the configuration. For example, a configuration shown in FIG. 12 may be applied. Referring to FIG. 12, the inlet portion 23 and the discharge portion 24 are disposed with the plurality of fins 10 interposed therebetween at the X-direction center of the cooler 3. The inlet portion 23 and the discharge portion 24 face each other in the direction orthogonal to the longitudinal direction of the cooler 3 (Y direction).

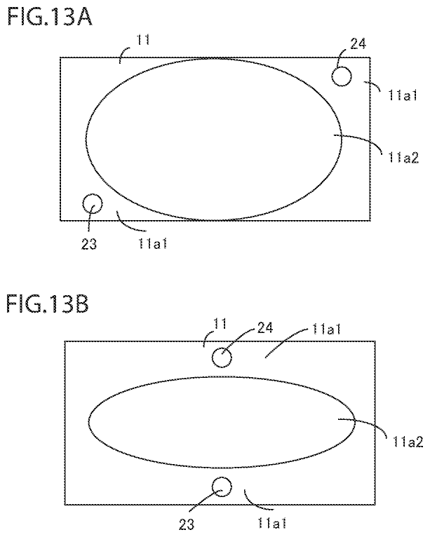

Having described the case where, according to the aforementioned embodiment, each of the inlet portion 23 and the discharge portion 24 has a long-hole shape that is long in the longitudinal direction (X direction), the invention is not limited to the configuration. The shapes, positions and so on of the inlet portion 23 and the discharge portion 24 can be changed as required. It should be noted that the entire lower surface of the bottom plate 11 may be parallel with a reference plane (XY plane), or at least surfaces around the inlet portion 23 and the discharge portion 24 may be parallel with the reference plane. Both of them are common in that the center of the upper surface of the bottom plate 11 projects upward with respect to the reference plane. In the latter case, as shown in FIGS. 13A and 13B, the lower surface of the bottom plate 11 may include, in planar view, a flat surface 11a1 that is provided around the inlet portion 23 and the discharge portion 24 and is parallel to the reference plane, and a concave surface 11a2 that is provided between the inlet portion 23 and the discharge portion 24 and is curved upward with respect to the reference plane.

According to the aforementioned embodiment, the number and positions of the semiconductor elements 7 are not limited to the configuration described above but can be changed as required.

According to the aforementioned embodiment, the number and layout of the circuit plates 15 are not limited to the configuration described above but can be changed as required.

Having described that, according to the aforementioned embodiment, the insulating substrate 6 and the semiconductor element 7 have a rectangular or square shape in planer view, the invention is not limited to the configuration. These components may be formed in a polygonal shape excluding those described above.

Having described the case where, according to the aforementioned embodiment, the semiconductor assemblies 2 are composed of three unit-modules aligned in the X direction in order of U-phase, V-phase and W phase, the invention is not limited to the configuration. The number and direction of arrangements of the unit modules can be changed as required. Although the case member 4 is provided integrally for the three phases of U-phase, V-phase and W-phase, the invention is not limited thereto but the case member 4 can be changed as required. The case member 4 may be divided to sections for unit modules.

Having described the embodiment and the variation examples, all or a part of each of the embodiment and the variation examples may be combined.

The invention is not limited to the aforementioned embodiment and variation examples, but various changes, replacements and variations can be made thereto without departing from the spirit and scope of the technical idea. Furthermore, if the technical idea can be realized by a different method with an advance of the technology or a different technology derived therefrom, the technical idea can be implemented by using the method. Therefore, the claims cover all embodiments that can be included within the scope of the technical idea.

Characteristic points according to the aforementioned embodiment are organized below.

A semiconductor apparatus according to the aforementioned embodiment includes a cooler having a top plate, one surface of which serves as a heat dissipation surface, a plurality of fins provided on the heat dissipation surface, a circumferential wall part provided so as to surround outer circumferences of the plurality of fins, and a bottom plate bonded to distal ends of the circumferential wall part and the plurality of fins, wherein a flow path for cooling water is formed from a space defined by the top plate, the plurality of fins, the circumferential wall part and the bottom plate, and a semiconductor element disposed on the other surface of the top plate with an insulating substrate interposed therebetween. The center of an upper surface of the bottom plate warps upward, and a lower surface of the bottom plate is machined so as to be flat.

In the semiconductor apparatus according to the aforementioned embodiment, the top plate, the circumferential wall part and the plurality of fins are integrated.

In the semiconductor apparatus according to the aforementioned embodiment, the lower surface of the bottom plate has an inlet portion and a discharge portion for the cooling water.

In the semiconductor apparatus according to the aforementioned embodiment, a plurality of the semiconductor elements are disposed side by side in a predetermined direction, the cooler has a rectangular shape in planar view that is long in the direction of alignment of the semiconductor elements, and the inlet portion and the discharge portion are disposed with the plurality of fins interposed therebetween.

In the semiconductor apparatus according to the aforementioned embodiment, the inlet portion and the discharge portion are disposed so as to diagonally face each other with the plurality of fins interposed therebetween.

In the semiconductor apparatus according to the aforementioned embodiment, the inlet portion and/or the discharge portion has a long-hole shape that is long in the direction of alignment.

In the semiconductor apparatus according to the aforementioned embodiment, a thickness of a part around the inlet portion and the discharge portion of the bottom plate is smaller than a thickness of the other parts of the bottom plate.

In the semiconductor apparatus according to the aforementioned embodiment, the bottom plate is thicker than the top plate is.

In the semiconductor apparatus according to the aforementioned embodiment, the bottom plate is acquired by coating a surface of a metallic material with plating having a predetermined thickness, and the surface of the metallic material is exposed on the machined lower surface of the bottom plate.

In the semiconductor apparatus according to the aforementioned embodiment, the lower surface of the bottom plate has a flatness equal to or smaller than 100 μm.

In the semiconductor apparatus according to the aforementioned embodiment, the cooler has a coefficient of linear expansion larger than that of the insulating substrate.

A semiconductor apparatus manufacturing method according to the aforementioned embodiment is a manufacturing method for a semiconductor apparatus having a cooler having a top plate, one surface of which serves as a heat dissipation surface, a plurality of fins provided on the heat dissipation surface, a circumferential wall part provided so as to surround outer circumferences of the plurality of fins, and a bottom plate bonded to distal ends of the circumferential wall part and the plurality of fins, wherein a flow path for cooling water is formed from a space enclosed by the top plate, the plurality of fins, the circumferential wall part and the bottom plate, and the method includes the steps of disposing a semiconductor element on the other surface of the top plate with an insulating substrate interposed therebetween, and performing flat machining on a lower surface of the bottom plate.

The manufacturing method for the semiconductor apparatus according to the aforementioned embodiment further includes the steps of disposing a case member so as to surround the insulating substrate and the semiconductor element on an upper surface of the cooler, and filling a sealing resin into a space enclosed by the case member and sealing the insulating substrate and the semiconductor element. The step of performing machining is performed immediately after the step of disposing the semiconductor element and before the step of disposing the case member.

### INDUSTRIAL APPLICABILITY

As described above, the present invention has an effect that sealing can be acquired with an inexpensive configuration and is particularly useful for a semiconductor apparatus and a semiconductor apparatus manufacturing method.

### REFERENCE SIGNS LIST

1 semiconductor apparatus

2 semiconductor assembly

3 cooler

4 case member

5 sealing resin

6 insulating substrate

7 semiconductor element

8 metallic wiring plate

9 top plate

10 fin

11 bottom plate

11a surface

12 circumferential wall part

13 insulating plate

14 heat dissipation plate

15 circuit plate

16 P terminal

17 N terminal

18 M terminal

19 control terminal

20 through-hole

21 collection

22 cooling case

23 inlet portion

24 discharge portion

25 fixing hole

26 housing

27 installation surface

28 O-ring

19 groove D gap S bonding material

What is claimed is:

1. A semiconductor apparatus, comprising:
a cooler including
a top plate having an inner surface which serves as a heat dissipation surface, and an outer surface opposite to the inner surface,
a bottom plate having an upper surface and a lower surface opposite to each other, and being disposed such that the upper surface faces the heat dissipation surface,
a plurality of fins, each of which is bonded to the heat dissipation surface of the top plate at one end thereof and to the upper surface of the bottom plate at an other end thereof, and
a circumferential wall surrounding the plurality of fins and being bonded to the heat dissipation surface of the top plate at one end thereof and to the upper surface of the bottom plate at an other end thereof, wherein a flow path for cooling water is formed by a space defined by the top plate, the plurality of fins, the circumferential wall and the bottom plate;
an insulating substrate disposed on the outer surface of the top plate of the cooler; and
a semiconductor element disposed on the insulating substrate, wherein
the lower surface of the bottom plate is a flat surface, and
the upper surface of the bottom plate is warped so that a center thereof protrudes with respect to a periphery thereof toward the semiconductor element.

2. The semiconductor apparatus according to claim 1, wherein the top plate, the circumferential wall and the plurality of fins are integrated.

3. The semiconductor apparatus according to claim 1, wherein the lower surface of the bottom plate has an inlet portion and a discharge portion for the cooling water.

4. The semiconductor apparatus according to claim 3, wherein
the cooler has a rectangular shape with long sides and short sides in a plan view of the semiconductor apparatus,
the semiconductor element is provided in plurality, the semiconductor elements being disposed side by side in a direction parallel to the long sides of the cooler, and
the inlet portion and the discharge portion are disposed with the plurality of fins interposed therebetween.

5. The semiconductor apparatus according to claim 4, wherein the inlet portion and the discharge portion are disposed such that the inlet portion diagonally faces the discharge portion with the plurality of fins interposed therebetween.

6. The semiconductor apparatus according to claim 4, wherein the inlet portion and/or the discharge portion has an elongated hole in a direction parallel to the long sides of the cooler.

7. The semiconductor apparatus according to claim 3, wherein thicknesses of an inlet area around the inlet portion and an discharge area around the discharge portion of the bottom plate are smaller than a thickness of the bottom plate in an area other than the inlet area and the discharge area.

8. The semiconductor apparatus according to claim 1, wherein a smallest thickness of the bottom plate is greater than a thickness of the top plate.

9. The semiconductor apparatus according to claim 1, wherein
the bottom plate is made of a metallic material, and has a plating film on an outer surface other than the lower surface of the bottom plate, and
the metallic material is exposed on the lower surface of the bottom plate.

10. The semiconductor apparatus according to claim 1, wherein the lower surface of the bottom plate has a flatness equal to or smaller than 100 μm.

11. The semiconductor apparatus according to claim 1, wherein the cooler has a coefficient of linear expansion larger than a coefficient of linear expansion of the insulating substrate.

12. The semiconductor apparatus according to claim 1, wherein a thickness of the bottom plate at the center is greater than at the periphery.

13. A manufacturing method for a semiconductor apparatus having a cooler a cooler including
a top plate having an inner surface which serves as a heat dissipation surface, and an outer surface opposite to the inner surface,
a bottom plate having an upper surface and a lower surface opposite to each other, and being disposed such that the upper surface faces the heat dissipation surface,
a plurality of fins, each of which is bonded to the heat dissipation surface of the top plate at one end thereof and to the upper surface of the bottom plate at an other end thereof, and
a circumferential wall surrounding the plurality of fins and being bonded to the heat dissipation surface of the top plate at one end thereof and to the upper surface of the bottom plate at an other end thereof, wherein a flow path for cooling water is formed by a space defined by the top plate, the plurality of fins, the circumferential wall and the bottom plate, the method comprising the steps of:
disposing a semiconductor element on the upper surface of the top plate with an insulating substrate interposed therebetween; and
performing flat machining on the lower surface of the bottom plate.

14. The manufacturing method for the semiconductor apparatus according to claim 13, further comprising the steps of:
disposing a case member so as to surround the insulating substrate and the semiconductor element on the outer surface of the cooler; and
filling a sealing resin into a space defined by the case member and the cooler, and sealing the insulating substrate and the semiconductor element,
wherein the performing machining is performed immediately after the disposing of the semiconductor element and before the disposing of the case member.
